(19) United States
(12) Patent Application Publication
(10) Pub. No.: US 2025/0370329 A1
(43) Pub. Date: Dec. 4, 2025

(54) CARBON-CONTAINING DIFFUSION BARRIER LAYER FOR PROTECTION OF CNT EUV PELLICLE

(71) Applicant: Taiwan Semiconductor Manufacturing Co., Ltd., Hsinchu (TW)

(72) Inventors: Pei-Cheng HSU, Hsinchu (TW); Hsin-Chang LEE, Hsinchu (TW)

(73) Assignee: Taiwan Semiconductor Manufacturing Co., Ltd., Hsinchu (TW)

(21) Appl. No.: 19/294,889

(22) Filed: Aug. 8, 2025

Related U.S. Application Data
(63) Continuation of application No. 18/658,399, filed on May 8, 2024.
(60) Provisional application No. 63/615,191, filed on Dec. 27, 2023.

(51) Int. Cl. G03F 1/62; G03F 1/24

(52) U.S. Cl. CPC G03F 1/62; G03F 1/24

(57) ABSTRACT

A pellicle including a pellicle membrane with improved stability to hydrogen plasma is provided. The pellicle membrane includes a plurality of carbon nanotubes (CNTs), where at least one carbon nanotube (CNT) of the plurality of CNTs is coated by a protection coating. The protection coating includes a plurality of nanostructures that includes a transition metal or an oxide, nitride, silicide or carbide thereof on a surface of the at least one CNT of the plurality of CNTs, a carbon-based diffusion barrier layer over at least the plurality of nanostructures, and a capping layer over at least the carbon-based diffusion barrier layer. The pellicle further includes a pellicle border attached to the pellicle membrane along a peripheral region of the pellicle membrane and a pellicle frame attached to the pellicle border.

### PRIORITY CLAIM AND CROSS-REFERENCE

This application is a Continuation of U.S. application Ser. No. 18/658,399, filed May 8, 2024, which claims the benefit of U.S. Provisional Patent Application No. 63/615,191, filed Dec. 27, 2023, each of which is incorporated by reference herein in its entirety.

### BACKGROUND

In the semiconductor integrated circuit (IC) industry, technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing.

In a process of manufacturing the IC devices, a lithography process is employed to form a circuit pattern on a wafer. In the lithography process, a photomask is used to transfer a desired pattern onto the wafer. When the photomask is contaminated with foreign materials, such as particles, from the ambient environment, defects may occur on the wafer to which the pattern of the photomask is transferred.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography system, in accordance with some embodiments.

FIG. 2A is a cross-sectional view of a pellicle-photomask structure, in accordance with some embodiments.

FIG. 2B is an isometric view of the pellicle-photomask structure of FIG. 2A, in accordance with some embodiments.

FIG. 2C illustrate a top view of a pellicle membrane of FIGS. 2A and 2B, in accordance with some embodiments.

FIG. 2D illustrates a cross-sectional view of a coated carbon nanotube of a network of carbon nanotubes illustrated in FIG. 2C, in accordance with some embodiments.

FIGS. 3A-3D are cross-sectional views of various examples of a protection coating illustrated in FIG. 2D, in accordance with some embodiments.

FIG. 4 is a flowchart illustrating a method for assembling a pellicle for a lithography process, in accordance with some embodiments.

FIGS. 5A-5E are cross-sectional of a pellicle at various stages of the method of FIG. 4, in accordance with some embodiment.

FIG. 6 is a flowchart illustrating a method for forming a protection coating on a carbon nanotube, in accordance with some embodiments.

FIGS. 7A-7D′ are cross-sectional views of the protection coating at various stages of the method of FIG. 6, in accordance with some embodiments.

FIG. 8 is a flowchart illustrating a method for forming a protection coating on a carbon nanotube, in accordance with some embodiments.

FIGS. 9A-9E′ are cross-section views of the protection coating at various stages of the method of FIG. 8, in accordance with some embodiments.

FIG. 10 is a flowchart illustrating a method for fabricating a semiconductor device, in accordance with some embodiments.

FIGS. 11A-11D are cross-sectional views of the semiconductor device at various stages of the method of FIG. 10, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Photolithographic patterning processes use a photomask that includes a desired mask pattern. The photomask may be a reflective mask or a transmission mask. In the process, ultraviolet light is reflected off the surface of the photomask (for a reflective mask) or transmitted through the photomask (for a transmission mask) to transfer the pattern to a photoresist on a semiconductor wafer. The exposed portion of the photoresist is photochemically modified. After the exposure, the photoresist is developed to define openings in the photoresist, and one or more semiconductor processing steps (e.g., etching, epitaxial layer deposition, metallization, etc.) are performed which operate on those areas of the wafer surface exposed by the openings in the photoresist. After this semiconductor processing, the photoresist is removed by a suitable resist stripper or the like.

The minimum feature size of the pattern is limited by the light wavelength. Deep ultraviolet (UV) lithography, for example using a wavelength of 193 nm or 248 nm in some standard deep UV platforms, typically employs transmission masks and provides a smaller minimum feature size than lithography at longer wavelengths. Extreme ultraviolet (EUV) light, which spans wavelengths from 124 nm down to 10 nm, is currently being used to provide even smaller minimum feature size. At shorter wavelengths, particle contaminants on the photomask can cause defects in the transferred pattern. Thus, a pellicle is used to protect the photomask from such particle contaminants. The pellicle includes a pellicle membrane which is attached to a mounting frame. The mounting frame supports the pellicle membrane over the photomask. Any contaminating particles which land on the pellicle membrane are kept out of the focal plane of the photomask. As a result, defects in the transferred pattern are reduced or prevented.

As the pellicle membrane remains covering the photomask during exposure, it is subject to stringent requirements in terms of absorption, durability, and particle shielding capability, etc. A pellicle membrane for an EUV reflective mask needs to meet several key requirements: (1) long lifetime in a hydrogen radical-rich operation environment within an EUV stepper/scanner; (2) strong mechanical strength to minimize the sagging effect during vacuum pumping and venting operations; (3) high or perfect blocking property for particles larger than about 20 nm (known as “killer particles”); and (4) good heat dissipation property to prevent the pellicle from being damaged by the EUV radiation. In the realm of EUV lithography, finding suitable pellicle membrane materials with high transmission and stability at EUV wavelengths has been a challenge.

Carbon nanotubes (CNTs) have emerged as a suitable material for pellicle membranes in EUV reflective photomasks. CNTs offer high EUV transmission and mechanical stability, along with low EUV scattering and reflectivity. However, during the EUV lithography process, the pellicle membrane may be exposed to hydrogen plasma, presenting a challenge as pristine CNTs are susceptible to damage from hydrogen plasma due to crystalline defects on the CNT surfaces. This damage may potentially shorten the lifespan of the pellicle membrane.

Embodiments of the present disclosure provide a pellicle membrane comprised a plurality of CNTs characterized by high transparency and endurance. The CNTs in the pellicle membrane are covered by a protective coating, safeguarding them from hydrogen radicals/ions present during exposure in the EUV scanner and thereby extending the membrane's lifespan. In these embodiments, the protective coating comprises either a single type or two different types of transition metal-containing nanostructures formed on the CNT surfaces for hydrogen reduction. These nanostructures, containing transition metals, are encapsulated by a carbon-based diffusion barrier layer to prevent heat buildup during EUV exposure. Lastly, a conformal capping layer is applied as the outermost layer, covering both the carbon-based diffusion barrier layer and, in some instances, the CNTs themselves, to inhibit hydrogen permeation.

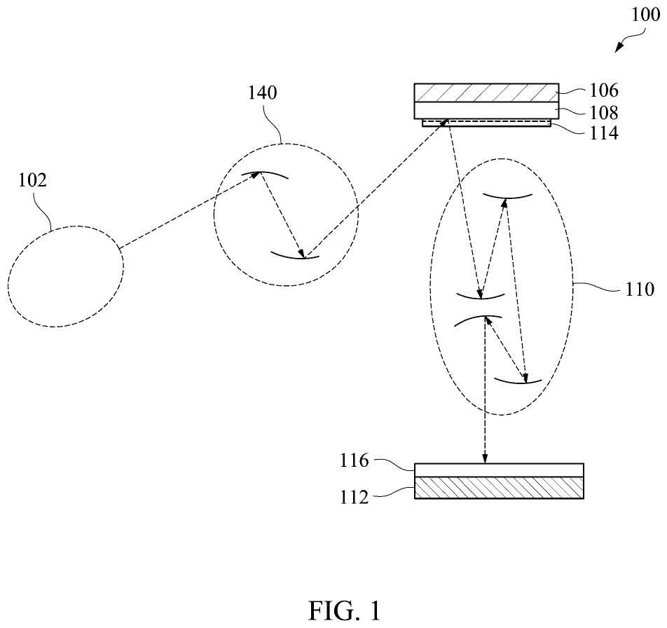

FIG. 1 is a schematic diagram of a lithography system 100, in accordance with some embodiments. The lithography system 100 may also be generically referred to as a “scanner” that is operable to perform lithographic processes including exposure with a respective radiation source and in a particular exposure mode.

In some embodiments, the lithography system 100 includes a high-brightness light source 102, an illuminator 104, a mask stage 106, a photomask 108, a projection optics module 110, and a substrate stage 112. In some embodiments, the lithography system 100 may include additional components that are not illustrated in FIG. 1. In some embodiments, one or more of the high-brightness light source 102, the illuminator 104, the mask stage 106, the photomask 108, the projection optics module 110, and the substrate stage 112 may be omitted from the lithography system 100 or may be integrated into combined components.

The high-brightness light source 102 may be configured to emit radiation having wavelengths in the range of approximately 1 nanometer (nm) to 250 nm. In some embodiments, the high-brightness light source 102 generates EUV light with a wavelength centered at approximately 13.5 nm; accordingly, in some embodiments, the high-brightness light source 102 may also be referred to as an “EUV light source.” However, it will be appreciated that the high-brightness light source 102 should not be limited to emitting EUV light. For instance, the high-brightness light source 102 may be utilized to perform any high-intensity photon emission from excited target material. In some embodiments, the high-brightness light source 102 may be an i-line, G-line, 248 nm, 193 nm, deep ultraviolet (DUV), sub-EUV, soft X-ray, or X-ray light source.

In embodiments where the lithography system 100 is a UV lithography system, the illuminator 104 may comprise various refractive optical components, such as a single lens or a lens system comprising multiple lenses (zone plates). In some embodiments, the illumination may include a mirror, concave mirror, convex mirror, lens, pellicle mirror, beam splitter, semi-transparent mirror, waveguide, dynamic gas lock (DGL) membrane. In embodiments where the lithography system 100 is an EUV lithography system, the illuminator 104 may comprise various reflective optical components, such as a single mirror or a mirror system comprising multiple mirrors. The illuminator 104 may direct light from the high-brightness light source 102 onto the mask stage 106, and more particularly onto the photomask 108 that is secured onto the mask stage 106. In embodiments where the high-brightness light source 102 generates light in the EUV wavelength range, the illuminator 104 comprises reflective optics.

The mask stage 106 may be configured to secure the photomask 108. In some embodiments, the mask stage 106 may include an electrostatic chuck (e-chuck) to secure the photomask 108. This is because the gas molecules absorb EUV light, and the lithography system 100 for EUV lithography patterning is maintained in a vacuum environment to minimize EUV intensity loss. Herein, the terms “photomask,” “mask,” and “reticle” may be used interchangeably. In one example, the photomask 108 is a reflective mask.

In some embodiments, a pellicle 114 may be positioned over the photomask 108, for example, between the photomask 108 and the substrate stage 112. The pellicle 114 may protect the photomask 108 from particles and may keep the particles out of focus, so that the particles do not produce an image (which may cause defects on a wafer during the lithography process).

The projection optics module 110 may be configured for imaging the pattern of the photomask 108 onto a semiconductor wafer 116 secured on the substrate stage 112. In some embodiments, the projection optics module 110 comprises refractive optics (such as for a UV lithography system). In some embodiments, the projection optics module 110 comprises reflective optics (such as for an EUV lithography system). The light directed from the photomask 108, carrying the image of the pattern defined on the photomask 108, may be collected by the projection optics module 110. The illuminator 104 and the projection optics module 110 may be collectively referred to as an “optical module” of the lithography system 100.

In some embodiments, the semiconductor wafer 116 may be a bulk semiconductor wafer. For instance, the semiconductor wafer 116 may comprise a silicon wafer. The semiconductor wafer 116 may include silicon or another elementary semiconductor material, such as germanium. In some embodiments, the semiconductor wafer 116 may include a compound semiconductor. The compound semiconductor may include gallium arsenide, silicon carbide, indium arsenide, indium phosphide, another suitable material, or a combination thereof.

In some embodiments, the semiconductor wafer 116 includes a silicon-on-insulator (SOI) substrate. The SOI substrate may be fabricated using a separation by implantation of oxygen (SIMOX) process, a wafer bonding process, another applicable process, or a combination thereof.

In some embodiments, the semiconductor wafer 116 comprises an undoped substrate. However, in other embodiments, the semiconductor wafer 116 comprises a doped substrate, such as a p-type substrate or an n-type substrate.

In some embodiments, the semiconductor wafer 116 includes various doped regions (not shown) depending on the design requirements of the semiconductor device structure. The doped regions may include, for example, p-type wells and/or n-type wells. In some embodiments, the doped regions are doped with p-type dopants. For example, the doped regions may be doped with boron or boron fluoride. In other embodiments, the doped regions are doped with n-type dopants. For example, the doped regions may be doped with phosphor or arsenic. In some embodiments, some of the doped regions are p-doped and other doped regions are n-doped.

In some embodiments, an interconnection structure may be formed over the semiconductor wafer 116. The interconnection structure may include multiple interlayer dielectric layers, including dielectric layers. The interconnection structure may also include multiple conductive features formed in the interlayer dielectric layers. The conductive features may include conductive lines, conductive vias, and/or conductive contacts.

In some embodiments, various device elements are formed in the semiconductor wafer 116. Examples of the various device elements may include transistors (e.g., metal oxide semiconductor field effect transistors (MOSFETs), complementary metal oxide semiconductor (CMOS) transistors, bipolar junction transistors (BJTs), high-voltage transistors, high-frequency transistors, p-channel and/or n-channel field effect transistors (PFETs and/or NFETs), diodes, or other suitable elements. Various processes may be used to form the various device elements, including deposition, etching, implantation, photolithography, annealing, and/or other applicable processes.

The device elements may be interconnected through the interconnection structure over the semiconductor wafer 116 to form integrated circuit devices. The integrated circuit devices may include logic devices, memory devices (e.g., static random access memory (SRAM) devices), radio frequency (RF) devices, input/output (I/O) devices, system-on-chip (SoC) devices, image sensor devices, other applicable devices, or a combination thereof.

In some embodiments, the semiconductor wafer 116 may be coated with a photoresist layer that is sensitive to EUV light. Various components including those described above may be integrated together and may be operable to perform lithography exposing processes.

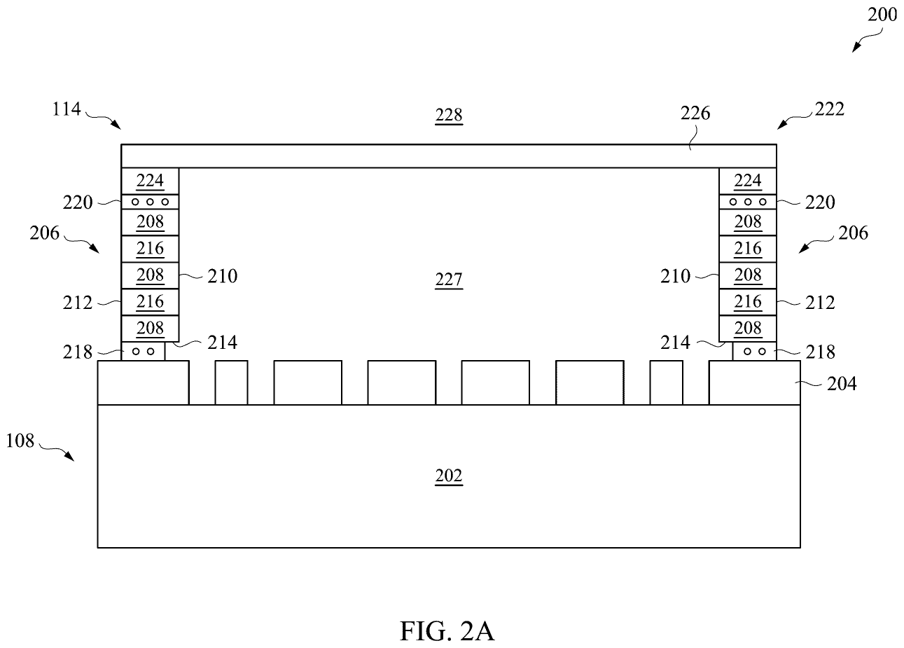

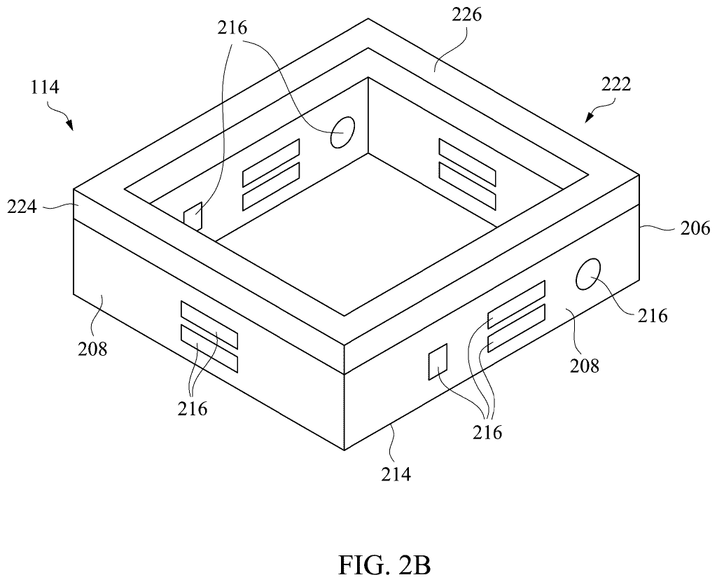

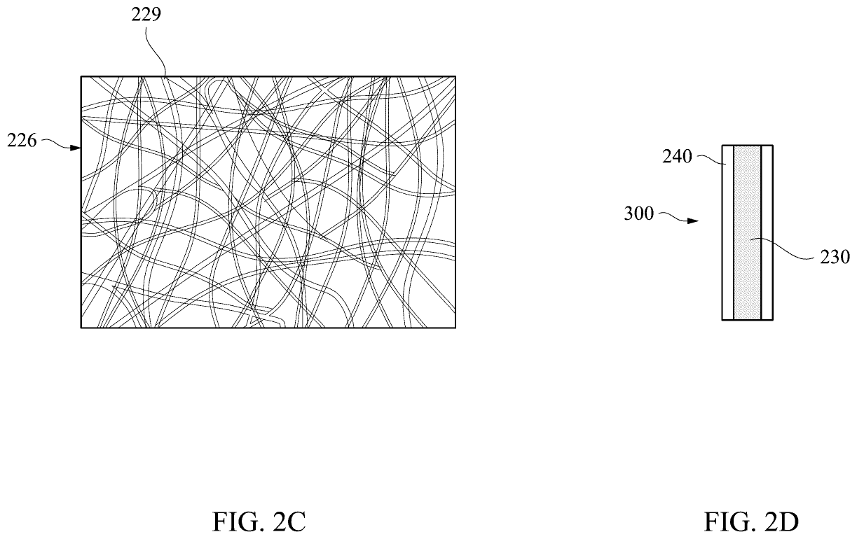

FIG. 2A is a cross-sectional view of a pellicle-photomask structure 200, according to some embodiments of the present disclosure. FIG. 2B is an isometric view of the pellicle-photomask structure 200 of FIG. 2A. As illustrated in FIGS. 2A and 2B, the photomask 108 may include a mask substrate 202 and a mask pattern 204 positioned over the mask substrate 202.

In some embodiments, the mask substrate 202 comprises a transparent substrate, such as fused silica that is relatively free of defects, borosilicate glass, soda-lime glass, calcium fluoride, a low thermal expansion material, an ultra-low thermal expansion material, or other applicable materials. The mask pattern 204 may be positioned over the mask substrate 202 as discussed above and may be designed according to the integrated circuit features to be formed over a semiconductor wafer (e.g., semiconductor wafer 116 of FIG. 1) during a lithography process. The mask pattern 204 may be formed by depositing a material layer and patterning the material layer to have one or more openings where beams of radiation may travel through without being absorbed, and one or more absorption areas which may completely or partially block the beams of radiation.

The mask pattern 204 may include metal, metal alloy, metal silicide, metal nitride, metal oxide, metal oxynitride, or other applicable materials. Examples of materials that may be used to form the mask pattern 204 may include, but are not limited to, Cr, MoₓSi_{y}, TaₓSi_{y}, Mo, NbₓO_{y}, Ti, Ta, CrₓN_{y}, MoₓO_{y}, MoₓN_{y}, CrₓO_{y}, TiₓN_{y}, ZrₓN_{y}, TiₓO_{y}, TaₓN_{y}, TaₓO_{y}, SiₓO_{y}, NbₓN_{y}, ZrₓN_{y}, AlₓO_{y}N_{z}, TaₓB_{y}O_{z}, TaₓB_{y}N_{z}, AgₓO_{y}, AgₓN_{y}, Ni, NiₓO_{y}, NiₓO_{y}N_{z}, and/or the like. The compound x/y/z ratio is not limited.

In some embodiments, the photomask 108 is an EUV mask. However, in some other embodiments, the photomask 108 may be an optical mask.

As illustrated in FIGS. 2A and 2B, the pellicle 114 may be positioned over the photomask 108. The pellicle 114 and the photomask 108 may form an enclosed inner volume 227 that is enclosed by the pellicle 114 and the photomask 108. The pellicle 114 and the photomask 108 separate the inner volume 227 from an outer environment 228. In some embodiments, the pellicle 114 includes a pellicle frame 206 that may be positioned over at least one of the mask substrate 202 and the mask pattern 204. In some embodiments, the pellicle frame 206 may be formed from Si, SiC, SiN, glass, a low coefficient of thermal expansion material (such as an Al alloy, a Ti alloy, Invar, Kovar, or the like), another suitable material, or a combination thereof. In some embodiments, suitable processes for forming the pellicle frame 206 may include machining processes, sintering processes, photochemical etching processes, other applicable processes, or a combination thereof.

In some embodiments, the pellicle frame 206 may include a side portion 208 having an inside surface 210 and an outside surface 212, where the inside surface 210 and the outside surface 212 are oriented on opposite sides of the side portion 208. The pellicle frame 206 may further include a bottom surface 214 or base that connects the inside surface 210 and the outside surface 212.

As further illustrated in FIGS. 2A and 2B, the pellicle-photomask structure 200 may further include a vent structure 216 formed in the side portion 208 and extending from the inside surface 210 through to the outside surface 212. In some embodiments, the vent structure 216 may comprise one or more apertures formed in the side portion 208 of the pellicle frame 206. The apertures may take any shape, including circular apertures, rectangular apertures, slit-shaped apertures, other shapes, or any combination thereof. The apertures may allow for a flow of air through a portion of the pellicle-photomask structure 200. In some embodiments, the vent structure 216 of the pellicle frame 206 may be formed so that at least one side portion 208 of the pellicle frame 206 includes one aperture formed in both the top of the side portion 208 (e.g., near the border 224) and another aperture formed in the bottom of the side portion 208 (e.g., near the mask pattern 204). In some embodiments, the apertures may include filters to minimize passage of outside particles through the vent structure 216.

In some embodiments, where the vent structure includes filters, the vent structure 216 may be formed together with the pellicle frame 206. In some embodiments, the vent structure 216 may be formed using a photochemical etching process, another applicable process, or a combination thereof.

In some other embodiments, where the vent structure includes filters, the vent structure 216 and the pellicle frame 206 may be formed separately, and an opening (not shown) may be formed in the side portion 208 of the pellicle frame 206. Afterwards, in some embodiments, the vent structure 216 may be placed into the opening in the side portion 208 of the pellicle frame 206. The vent structure 216 may then be bonded to the pellicle frame 206, e.g., by a brazing process, a direct diffusion bond process, a eutectic bonding process, another applicable process, or a combination thereof. In some embodiments, the vent structure 216 may prevent the pellicle membrane 226 from rupturing during the EUV lithography process.

As further illustrated in FIGS. 2A and 2B, the pellicle-photomask structure 200 may further include a pellicle frame adhesive 218 positioned between the pellicle frame 206 and the mask substrate 202.

In some embodiments, the pellicle frame adhesive 218 may be made of thermoplastic elastomer or other polymeric adhesive material curable upon heating or under UV light. In various examples, the adhesive includes polybutene resin, polyvinyl acetate resin, acrylic resin, silicone resin, epoxy resin, or the like.

In some embodiments, a surface treatment may be performed on the pellicle frame 206 to enhance the adhesion of the pellicle frame 206 to the pellicle frame adhesive 218. In some embodiments, the surface treatment may include an oxygen plasma treatment, another applicable treatment, or a combination thereof. However, in other embodiments, no surface treatment may be performed on the pellicle frame 206.

The pellicle-photomask structure 200 may further include a pellicle membrane adhesive 220 positioned over the pellicle frame 206. In some embodiments, the pellicle membrane adhesive 220 may be formed from a thermoplastic elastomer type adhesive, a polystyrene type adhesive, an acrylic type adhesive, a silicon-based adhesive, an epoxy type adhesive, another suitable adhesive, or a combination thereof. In some embodiments, the pellicle membrane adhesive 220 may be formed from a material that is different from the material making up the pellicle frame adhesive 218.

As further illustrated in FIGS. 2A and 2B, the pellicle-photomask structure 200 may further include a pellicle membrane assembly 222 positioned over the pellicle frame 206 and the pellicle membrane adhesive 220. As illustrated, the pellicle membrane adhesive 220 may be positioned between the pellicle membrane assembly 222 and the pellicle frame 206.

In some embodiments, the pellicle membrane assembly 222 may include a border 224 positioned over the pellicle membrane adhesive 220 and a pellicle membrane 226 positioned over the border 224. In some embodiments, the border 224 may be formed from Si. In further embodiments, the border 224 may be formed from boron carbide, graphene, carbon nanotube, SiC, SiN, SiO₂, SION, Zr, Nb, Mo, Cd, Ru, Ti, Al, Mg, V, Hf, Gc, Mn, Cr, W, Ta, Ir, Zn, Cu, F, Co, Au, Pt, Sn, Ni, Te, Ag, another suitable material, an allotrope of any of these materials, or a combination thereof. The border 224 may mechanically support the pellicle membrane 226 around the periphery of the pellicle membrane 226. The border 224 may, in turn, be mechanically supported by the pellicle frame 206 when the pellicle-photomask structure 200 is fully assembled. That is, the pellicle frame 206 may mechanically support the border 224 and the pellicle membrane 226 of the pellicle membrane assembly 222 on the photomask 108.

The pellicle membrane 226 has a complex refractive index with an n value in the range from about 0.8 to about 1 and a k value in the range from about 0.01 to 0.1. In some embodiments, the pellicle membrane 226 may be formed from a network 229 of a plurality of CNTs. The CNTs may be single-wall CNTs (SWCNTs), double-wall CNTs (DWCNTs), multi-wall CNTs (MWCNTs), or combinations thereof. The wall thickness of the CNTs may range from about 0.01 nm to about 100 nm. The CNTs in the pellicle membrane 226 may be individual, unbundled CNTs or bundled individual CNTs. The bundled individual CNTs form CNT bundles. The term “CNT bundle” refers to more than 10 individual CNTs wrapped around each other. While there is no theoretical limit, in particular embodiments a CNT bundle may be formed from a maximum of 20 CNTs. FIG. 2C, for instance, illustrates an example of the pellicle membrane 226 of FIGS. 2A and 2B. In the example illustrated in FIG. 2C, the pellicle membrane 226 includes a CNT membrane layer formed from a network 229 of randomly oriented CNTs. In some embodiments, the pellicle membrane 226 has a multi-layer structure comprising a plurality of CNT membrane layers. In some embodiments, each of the plurality of CNT membrane layers is formed from a network 229 of randomly oriented CNTs. In other embodiments, the plurality of CNT membrane layers are formed from directionally oriented CNTs with CNTs in adjacent layers aligned at an angle relative to each other.

In some embodiments, the network 229 of CNTs making up the pellicle membrane 226 may have a structure density of between 0.2 and 1, depending on the desired percentage of radiation to be transmitted by the pellicle membrane 226. For instance, the pellicle membrane 226 has been shown to achieve up to approximately 90% light transmittance. The precise structure density may be chosen to maximize EUV radiation transmission while minimizing passage of particles through the pellicle membrane 226. For instance, although a looser structure density may allow for greater EUV radiation transmission, the looser structure density may also allow particles to fall through to the photomask 108.

In some embodiments, the pellicle membrane 226 may have a thickness ranging from about 5 nm to about 100 nm. In more particular embodiments, the thickness of the pellicle membrane 226 is from about 20 nm to about 50 nm. These ranges have been found to provide sufficient robustness to the pellicle membrane 226, while also providing high EUV transmission. In general, the thicker the pellicle membrane 226, the more robust the pellicle membrane 226 will be; however, if the pellicle membrane 226 is too thick, the percentage of EUV transmission may decrease. Thus, the disclosed ranges strike a balance between these two aims. In some embodiments, the pellicle membrane has a transparency no less than 50%.

CNTs are susceptible to degradation from exposure to hydrogen plasma, such as the type employed during operation or maintenance of a photolithography system. To extend the CNT pellicle membrane lifetime in the scanner environment of EUV-induced hydrogen-based plasma, in embodiments of the present disclosure, one or more CNTs in the network of the plurality of CNTs are coated with a protection coating. For example, in some embodiments, more than 90% of individual CNTs in the network of the plurality of CNTs are coated with the protection coating. In some embodiments, more than 95%, more than 98%, or 100% of individual CNTs in the network 229 of the plurality of CNTs are coated with the protection coating. FIG. 2D, for instance, illustrates a cross-sectional view of a coated CNT 300 in the network 229 of the plurality of CNTs illustrated in FIG. 2C. As shown in FIG. 2D, a pristine CNT 230 is coated with a protection coating 240 to provide a coated CNT 300. In some embodiments, the coated CNT 300 has a core-shell structure including a CNT core and a protection coating shell. In embodiments of the present disclosure, the protection coating 240 features a multilayer structure including a metal-containing seed layer, a carbon-based diffusion barrier layer, and a capping layer for protecting the pristine CNT 230 from damage caused by hydrogen plasma, as detailed below.

In some embodiments, a total thickness of the protection coating 240 is in the range from about 1 nm to about 40 nm. When the thickness of the protection coating 240 is greater than this range, EUV transmittance of the pellicle membrane 226 may be decreased, and when the thickness of the protection coating is smaller than this range, mechanical strength of the pellicle membrane 226 may be insufficient.

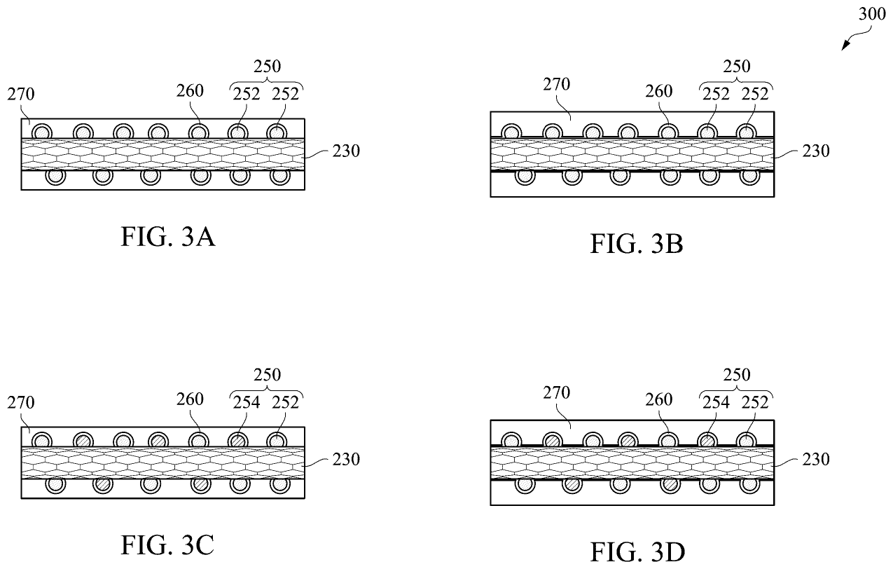

FIGS. 3A-3D are cross-sectional views illustrating various examples of a coated CNT 300 within the network of multiple CNTs, in accordance with embodiments of the present disclosure. The coated CNTs 300 depicted in FIGS. 3A-3D vary from each other based on the compositions and/or configurations of the protection coating 240 surrounding the CNT 230.

FIG. 3A is a cross-sectional view of a first example of a coated CNT 300 in the network of the plurality of CNTs 230, in according with some embodiments. As illustrated in FIG. 3A, the protection coating 240 that surrounds the CNT 230 includes a seed layer 250, a diffusion barrier layer 260 over the seed layer 250, and a capping layer 270 over the diffusion barrier layer 260.

The seed layer 250 is formed on the surface of the CNT 230, but does not fully covering it. The seed layer 250 is adapted to decrease the amount of hydrogen radicals reaching the surface of the CNT 230. In some embodiments, the seed layer 250 includes a plurality of nanostructures 252 having a dimension in the nanometer range. Discrete nanostructures 252 are employed rather than a continuous conformal layer to minimize the impact on the EUV transmittance resulting from the presence of these nanostructures 252, which absorb EUV radiation. Moreover, the geometry of nanostructures 252 offers a higher surface area compared to the continuous conformal layer, leading to improved hydrogen or oxygen reduction by increasing the reaction area. In some embodiments, the nanostructures 252 may have different morphologies such that the cross-sectional profiles of the nanostructures 252 are different from each other. In some embodiments, the nanostructures 252 may have a dimension in the range from about 0.5 nm to about 5 nm. The nanostructures 252 can adopt any shapes. For example, in some embodiments, the nanostructures 252 may be nano-grains, nano-islands, nano-cubes, nanosheets, or combinations thereof. In some embodiments and as shown in FIG. 3A, the seed layer 250 includes a plurality of nano-grains 252 over the surface of the CNT 230. In some embodiments, the nanostructures 252 are uniformly distributed on the surface of CNT 230. In some other embodiments, the nanostructures 252 are randomly distributed on the surface of CNT 230. The dimensions of the nanostructures 252 are selected such that the nanostructures 252 will not block the transmission of the EUV light.

In some embodiments, the nanostructures 252 are composed of a material that can effectively react with hydrogen radicals generated during the EUV exposure in an EUV scanner, thus mitigating the damage to the CNT 230 caused by these hydrogen radicals. In some embodiments, the material in the nanostructures 252 can also serve as a catalyst for growing a 2-dimendional carbon material, such as graphene, to be used as the diffusion barrier layer 260. In some embodiments, the nanostructures 252 are composed of a transition metal or a compound thereof. Examples of suitable transition metals include, but are not limited to, chromium (Cr), cobalt (Co), copper (Cu), iridium (Ir), iron (Fc), gold (Au), manganese (Mn), molybdenum (Mo), nickel (Ni), niobium (Nb), palladium (Pd), platinum (Pt), rhodium (Rh), ruthenium (Ru), silver (Ag), tantalum (Ta), titanium (Ti), tungsten (W), vanadium (V), and zirconium (Zr). In some embodiments, the compound of such a transition metal may include an oxide, nitride, silicide, or carbide of the transition metal. In some embodiments, the nanostructures 252 include Co, Ir, Fe, Nb, Ni, Pt, Rh, Ru, Ti, RuO₂, RuSi₂, RuSi, Ru₂Si₃, Nb₂O₅, Mo, MoO₂, or TiO₂. In some embodiments, the nanostructures 252 include Ru or RuO₂.

In some embodiments, the nanostructures 252 may be formed by sol-gel, E-beam evaporation, chemical vapor deposition (CVD), plasma enhanced CVD (PECVD), atomic layer deposition (ALD), plasma enhanced ALD, thermal ALD, electrodeposition, electroless deposition, or other suitable deposition techniques.

The diffusion barrier layer 260 is formed over the seed layer 250. The diffusion barrier layer 260 is adapted to prevent agglomeration of the nanostructures 252. Due to their small size and high surface energy associated therewith, the nanostructures 252 have a tendency to agglomerate and form larger aggregates when heat accumulates on the nanostructures 252. This agglomeration can lead to the migration or diffusion of the nanostructures 252. As a result, the nanostructure aggregates reduce the EUV transmission of the pellicle membrane 226. The formation of the diffusion barrier layer 260, which encapsulates the nanostructures 252 and functions as a barrier to prevent migration or diffusion of the nanostructures 252, helps to suppress the agglomeration of the nanostructures 252. As a result, the reliability of the pellicle membrane 226 is improved, while the high EUV transmittance of the pellicle membrane 226 is maintained. In the first example as shown in FIG. 3A, the diffusion barrier layer 260 is formed as a discontinuous layer, presenting only on the surfaces of the nanostructures 252, while the surfaces of the portions of the CNT 230 between the nanostructures 252 remain uncovered. The diffusion barrier layer 260 may comprise a carbon-based material with lower EUV absorption and higher EUV transmittance compared to other non-carbon based materials. The carbon-based material also exhibits high thermal conductivity of 400 Wm⁻¹ K⁻¹ or greater, which helps to prevent the migration of nanostructures 252 caused by the thermal accumulation during deposition processes for the formation of the protection coating 240 or during EUV exposure in EUV lithography. In some embodiments, the thermal conductivity of the carbon-based material ranges from 400 Wm⁻¹ K⁻¹ to 4050 Wm⁻¹ K⁻¹. In some embodiments, the diffusion barrier layer 260 may include graphene, amorphous carbon, graphite, or diamond-like carbon. In certain embodiments, the diffusion barrier layer 260 includes graphene having a thermal conductivity about 4000±50 Wm⁻¹ K⁻¹, which is greater than the thermal conductivity of the material (e.g., Ru (120±50 Wm⁻¹ K⁻¹) or RuO₂ (50±50 Wm⁻¹ K⁻¹)) that consistutes the underlying nanostructures 252. As a result, the graphene-based diffusion barrier layer 260 can quickly dissipate the heat load, preventing the accumulation of heat on the Ru-containing nanostructures during EUV exposure.

In some embodiments, the diffusion barrier layer 260 may be a single layer of carbon-based material. In some other embodiments, the diffusion barrier layer 260 may include a plurality of layers of carbon-based material. In some embodiments, the diffusion barrier layer 260 may include from 1 to 10 layers of carbon-based material. In some embodiments, the diffusion barrier layer 260 may be a single graphene layer (e.g., a one atomic thick graphene layer). In some other embodiments, the diffusion batter layer may include two or more graphene layers. In some embodiments, the diffusion barrier layer 260 has a thickness ranging from about 0.2 nm to 5 nm. When the thickness of the diffusion barrier layer 260 exceeds this range, EUV transmittance of the pellicle membrane may be decreased. Conversely, when the thickness of the diffusion barrier layer 260 falls below this range, the diffusion barrier layer 260 may not be able to effectively prevent nanostructure migration due to inadequate heat dissipation.

The diffusion barrier layer 260 may be formed by a suitable deposition technique, such as CVD or PECVD. In some embodiments, when the diffusion barrier layer 260 is made of graphene, the diffusion barrier layer 260 may be formed by CVD using the nanostructures 252 as the catalyst. In some embodiments, the diffusion barrier layer 260 is formed as a conformal layer around the exposed surfaces of the nanostructures 252.

The capping layer 270 is applied as a conformal layer over both the diffusion barrier layer 260 and the CNT 230. As the nanostructures 252 and the diffusion barrier layer 260 only partially cover the surface of the CNT 230, the capping layer 270 comes into contact with both the surface of the CNT 230 and the surface of the diffusion barrier layer 260. The capping layer 270 is adapted to prevent hydrogen permeation, thereby protecting the CNT 230 and the diffusion barrier layer 260 from damage caused by hydrogen radicals. In some embodiments, the capping layer 270 may include a dielectric material, for example, a dielectric oxide such as silicon dioxide (SiO₂) aluminum oxide (Al₂O₃), niobium oxide (Nb₂O₅), platinum dioxide (PtO₂), ruthenium oxide (RuO₂), titanium oxide (TiO₂), or yttrium oxide (Y₂O₃); a dielectric nitride such as silicon nitride (SiN), aluminum nitride (AlN), titanium nitride (TiN), yttrium nitride (YN), or boron nitride (BN); a dielectric oxynitride such as silicon oxynitride (SiON), aluminum oxynitride (AlON), or titanium oxynitride (TiON); a dielectric carbide such as silicon carbide (SiC); a dielectric oxycarbide such as silicon oxycarbide (SiOC), or a dielectric oxysilicide such as yttrium oxysilicide (YOSi).

The capping layer 270 is thin and thus does not degrade the transparency of the pellicle membrane 226 to EUV light. In some embodiments, the thickness of the capping layer 270 may range from about 1 nm to about 5 nm. The capping layer 270 may be formed by a suitable conformal deposition technique such as CVD, PECVD, ALD, thermal ALD, or PVD. In some embodiments, the capping layer 270 is formed as a conformal layer surrounding the CNT 230. In some embodiments, the capping layer 270 may be a single layer. In some other embodiments, the capping layer 270 may consist of multiple layers made of different materials as listed above.

FIG. 3B is a cross-sectional view of a second example of a coated CNT 300 in the network of the plurality of CNTs, in according with some embodiments. As illustrated in FIG. 3B, the protection coating 240 that surrounds the CNT 230 includes a seed layer 250 comprising a plurality of nanostructures 252 over the CNT 230 that partially covers the surface of the CNT 230, a diffusion barrier layer 260 over the nanostructures 252 and the CNT 230, and a capping layer 270 over the diffusion barrier layer 260. In contrast to the first example illustrated in FIG. 3A, where the diffusion barrier layer 260 is formed as a discontinuous layer covering only the nanostructures 252, in the second example, the diffusion barrier layer 260 is formed as a continuous conformal layer covering not only the nanostructures 252 but also portions of the CNT 230 that are not covered by the nanostructures 252. As a result, the capping layer 270 subsequently formed is only in contact with the diffusion barrier layer 260. In some embodiments, the continuous diffusion barrier layer 260 may be formed by a conformal deposition process such as CVD or PECVD.

FIG. 3C is a cross-sectional view of a third example of a coated CNT 300 in the network of the plurality of CNTs, in according with some embodiments. As illustrated in FIG. 3C, the protection coating 240 that surrounds the CNT 230 includes a seed layer 250 over a surface of the CNT 230, a diffusion barrier layer 260 over seed layer 250, and a capping layer 270 over the diffusion barrier layer 260 and the CNT 230. In contrast to the first example illustrated in FIG. 3A, where the seed layer 250 includes a single type of nanostructures 252 made of the same material, in the third example, the seed layer 250 contains two types of nanostructures, i.e., a plurality of first nanostructures 252 and a plurality of second nanostructures 254, made of different materials. The first and second nanostructures 252, 254 may be nano-grains, nano-islands, nano-cubes, nanosheets, or combinations thereof. In some embodiments, the first and second nanostructures 252, 254 are uniformly distributed on the surface of CNT 230 so that the spacings between adjacent nanostructures 252, 254 are the same. In some embodiments, the first and second nanostructures 252, 254 are randomly distributed on the surface of CNT 230 such that the spacings between adjacent nanostructures 252, 254 are different. In some embodiments, the first and second nanostructures 252, 254 are arranged such that one or more first nanostructures 252 are separated from one or more first nanostructures 252 by one or more second nanostructures 254. In some embodiments, the first and second nanostructures 252, 254 are arranged such that the first nanostructures 252 are separated from each other by one or more second nanostructures 254. The dimensions of the first and second nanostructures 252, 254 are selected such that the first and second nanostructures 252, 254 will not block the transmission of the EUV light. In some embodiments, the first and second nanostructures 252, 254 may independently have a dimension in the range from about 0.5 nm to about 5 nm. In some embodiments, the first and second nanostructures 252, 254 have the same dimension. In some embodiments, the first nanostructures 252 may have different morphologies such that the cross-sectional profiles of the first nanostructures 252 are different from each other. In some embodiments, the second nanostructures 254 may have different morphologies such that the cross-sectional profiles of the second nanostructures 254 are different from each other. In some embodiments, the profiles of the first nanostructures 252 may be the same or different from the profiles of the second nanostructures 254.

In some embodiments, the first and second nanostructures 252, 254 are independently composed of a transition metal or a compound thereof. Examples of suitable transition metals include, but are not limited to, chromium (Cr), cobalt (Co), copper (Cu), iridium (Ir), iron (Fe), gold (Au), manganese (Mn), molybdenum (Mo), nickel (Ni), niobium (Nb), palladium (Pd), platinum (Pt), rhodium (Rh), ruthenium (Ru), silver (Ag), tantalum (Ta), titanium (Ti), tungsten (W), vanadium (V), and zirconium (Zr). In some embodiments, the compound may include an oxide, nitride, silicide, or carbide of a transition metal. In some embodiments, the first nanostructures 252 and the second nanostructures 254 independently comprise Co, Ir, Fc, Nb, Ni, Pt, Rh, Ru, Ti, RuO₂, RuSi₂, RuSi, Ru₂Si₃, Nb₂O₅, Mo, MoO₂, or TiO₂. In some embodiments, the first nanostructures 252 include Ru, RuO₂, RuSi₂, RuSi, or Ru₂Si₃, while the second nanostructures 254 include Nb, Nb₂O₅, Mo, MoO₂, Ti, TiO₂, Ir, Pt, Rh, Ni, Fe, or Co. In some embodiments, the first nanostructures 252 include Ru or RuO₂, and the second nanostructures 254 include Ir or Pt. In the third example, the use of two types of nanostructures made of different materials enables the simultaneous optimization of hydrogen reduction and the EUV transmission.

In the third example, since the seed layer 250 includes the two types of the nanostructures (i.e., first nanostructures 252 and second nanostructures 254), the diffusion barrier layer 260 encapsulates both the first and second nanostructures 252, 254.

FIG. 3D is a cross-sectional view of a fourth example of a coated CNT 300 in the network of the plurality of CNTs, in according with some embodiments. As illustrated in FIG. 3D, the protection coating 240 that surrounds the CNT 230 includes a seed layer 250 comprising a plurality of first nanostructures 252 and a plurality of second nanostructures 254 over the surface of the CNT 230, a diffusion barrier layer 260 over the seed layer 250 and the CNT 230, and a capping layer 270 over the diffusion barrier layer 260. In contrast to the third example illustrated in FIG. 3C, where the diffusion barrier layer 260 is formed as a discontinued layer to cover only the first and second nanostructures 252, 254, in the fourth example, the diffusion barrier layer 260 is formed as a continuous conformal layer covering not only the first and second nanostructures 252, 254 but also portions of the CNT 230 not covered by the first and second nanostructures 252, 254.

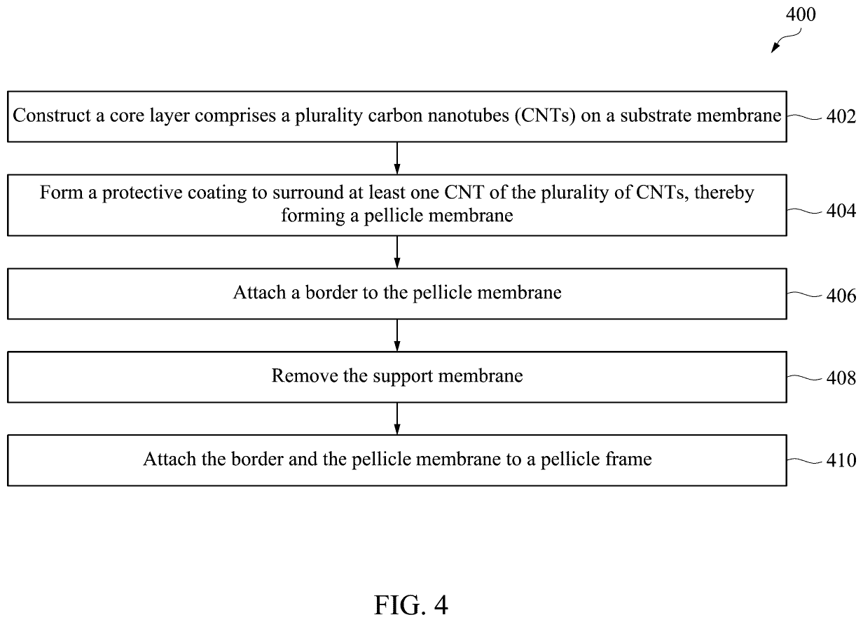

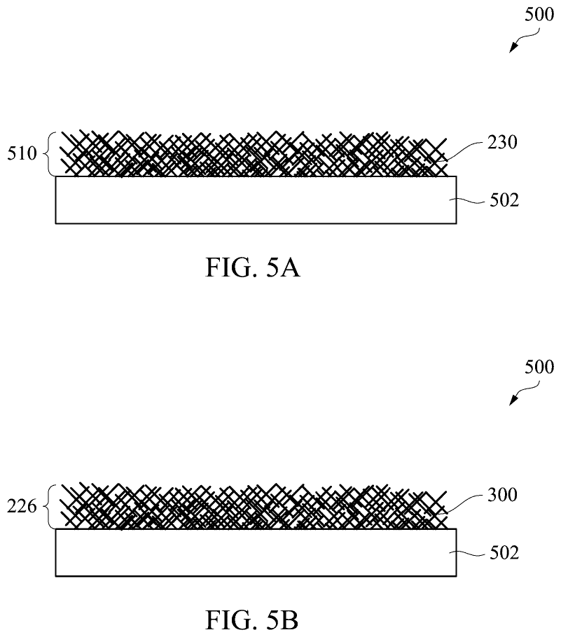

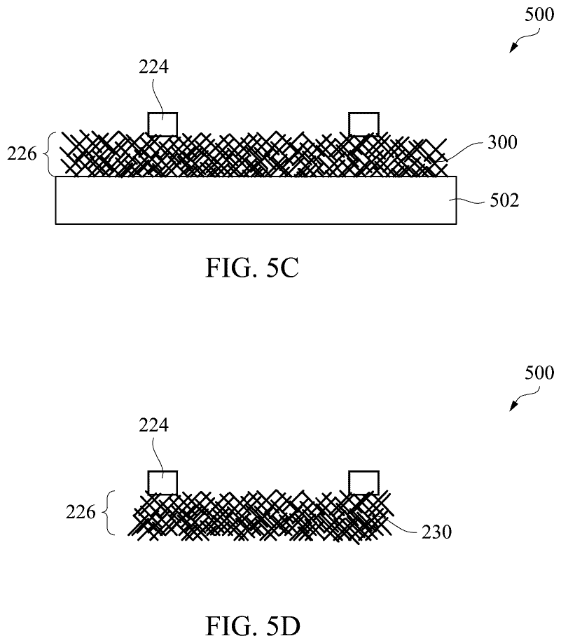

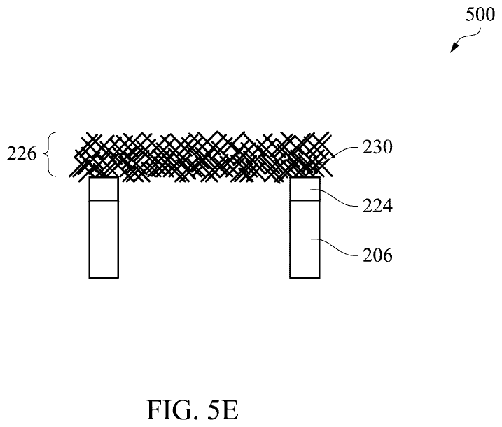

FIG. 4 is a flowchart illustrating a method 400 for assembling a pellicle for a lithography process, in accordance with some embodiments. For instance, the method 400 may be performed to assemble the pellicle 114 illustrated in FIGS. 1 and 2A-2B. The method 400 may be performed using one or more different machines, under the control of a controller or processor. FIGS. 5A-5E are cross-sectional views of a pellicle 500 at various stages of the method 400, in accordance with some embodiments. The method 400 is discussed in detail below, with reference to the pellicle 500 of FIGS. 5A-5E.

In step 402 of the method 400, a CNT membrane layer 510 comprising a plurality of CNTs 230 may be constructed on a support membrane 502, as shown in FIG. 5A. The plurality of CNTs 230 may include a plurality of individual CNTs or a plurality of CNT bundles. The CNT may be a single-wall, a double-wall, a multi-wall CNT, or combinations thereof. The support membrane 502 may comprise, for instance, polyvinyl alcohol (PVA), polystyrene (PS), polyethylene terephthalate (PET), polyvinylidene fluoride (PVDF), or a chemical vapor deposited poly(p-xylylene) polymer (e.g., parylene C). In some embodiments, the CNT membrane layer 510 may be constructed using a roll-to-roll process in a plasma environment, such as a plasma reacting chamber in which the reacting gas may comprise, for instance, CₓH_{y}, H₂, Ar, O₂, another suitable gas, or any combination thereof.

In step 404 of the method 400, a protection coating is formed to surround at least one CNT 230 of the plurality of CNTs 230, thereby forming a pellicle membrane 226 comprising a plurality of coated CNTs 300, as shown in FIG. 5B. The processing steps for formation of the protection coating on the CNT 230 will be described in detail below.

In step 406 of the method 400, a border 224 is attached to the pellicle membrane 226 along a peripheral portion of the pellicle membrane 226, as shown in FIG. 5C. In some embodiments, the border 224 may have a rectangular shape. To attach the border 224 to the pellicle membrane 226, in some embodiments, the border 224 is first brought into physical contact with the pellicle membrane 226. The border 224 is then pressed against the pellicle membrane 226 to fix the pellicle membrane 226 to border 224. In some embodiments, the border 224 and the pellicle membrane 226 are held together by van der Waals forces. In some embodiments, to ensure a better adhesion, an adhesive is used to attach the border 224 to the pellicle membrane 226.

In step 408 of the method 400, the support membrane 502 is removed to make the pellicle membrane 226 freestanding, as shown in FIG. 5D. In some embodiments, when the support membrane 502 is made of an organic material, the support membrane 502 may be removed by wet etching using an organic solvent.

In step 410 of the method 400, the border 224 and pellicle membrane 226 are attached to a pellicle frame 206 including a vent structure. The pellicle frame 206 may have the same shape as the border 224 (e.g., rectangular shape), as shown in FIG. 5E.

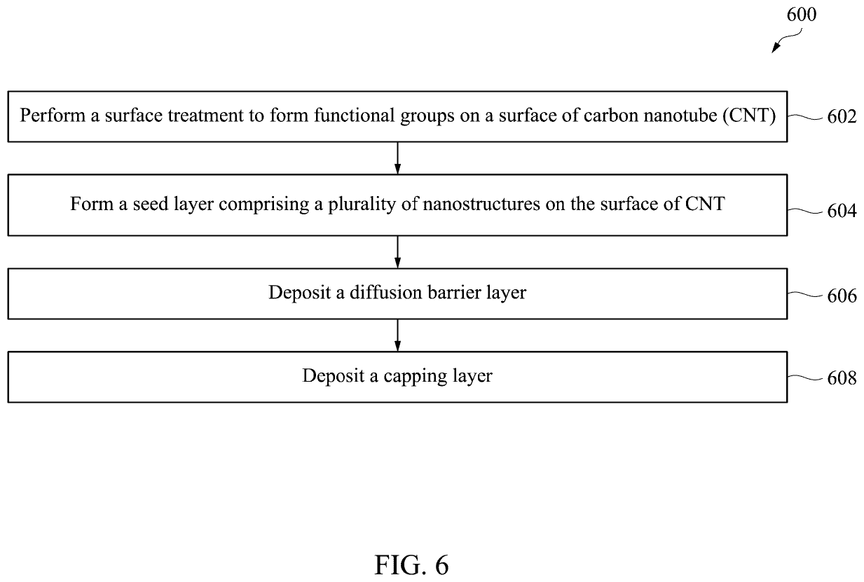

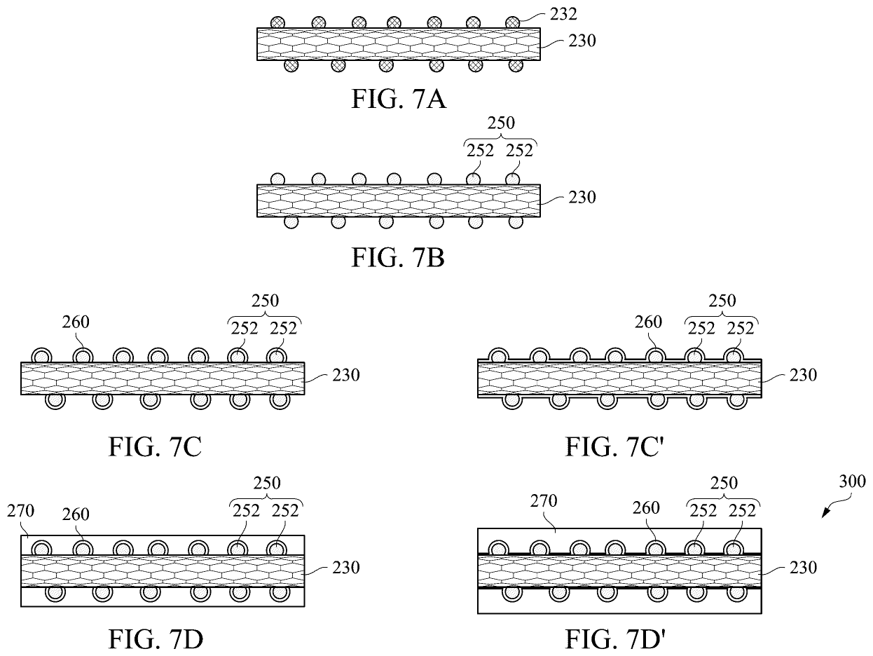

FIG. 6 is a flowchart illustrating a method 600 for forming a protection coating 240 on a CNT 230, in accordance with some embodiments. FIGS. 7A-7D′ are cross-sectional views of a coated CNT 300 at various stages of the method 600, in accordance with some embodiments. The method 600 is discussed in detail below, with reference to the coated CNT 300 of FIGS. 7A-7D′.

In step 602 of the method 600, a surface treatment is performed to form functional groups 232 on the CNT surface, as shown in FIG. 7A. The functional groups 232 serve as reactive sites for formation of nanostructures 252. In some embodiments, the functional groups 232 include hydroxyl (—OH) groups, carbonyl (—C═O) groups, sulfhydryl groups, carboxyl groups, amino groups, phosphate groups, or combinations thereof. In some embodiments, the functional groups 232 may be uniformly formed on the surface of the CNT 230. In some other embodiments, the functional groups 232 may be randomly formed on the surface of the CNT 230.

In some embodiments, the surface treatment includes applying a solution to the CNT membrane or soaking or immersing the CNT membrane layer into the solution. The solution may include an organic or inorganic acid solution, and/or a polymer or an organic compound having one or more of the functional groups. In some embodiments, the solution includes HNO₃, H₂SO₄, 5-isocyanato-isophthaloyl chloride (ICIC), dodecylamine (DDA), polycaprolactone (PCL), polyacrylic acid (PAA), polydopamine (Pdop), polyaniline (PANI), polymethyl triethyl ammonium chloride (PMTAC), poly(ethylene glycol) methyl ether methacrylate (PEGMA), polysulfobetaine methacrylate (PSBMA), 3-aminopropyl triethoxysilane (APTS), 1,3-phenylenediamine (mPDA), or combination thereof. In some embodiments, the solution includes HNO₃, H₂SO₄, H₂SO₄/HNO₃, HCl/H₂SO₄/HNO₃, H₂O₂, KMnO₄, K₂Cr₂O₇/H₂SO₄, or KMnO₄/H₂SO₄.

In some embodiments, the surface treatment includes a gas soaking by applying one or more gases to the CNT membrane layer. In some embodiments, the CNT membrane layer and/or the gas are heated at a temperature in a range from about 300° C. to 1200° C. In other embodiments, the temperature is in a range from about 600° C. to 800° C. When the temperature is too high, the membrane may be damaged, and when the temperature is too low, the surface modification may be insufficient. The soaking gas includes one or more of Ar, He, H₂, Ne, N₂ and NH₃, without oxygen. In some embodiments, O₂ is used alternatively or additionally.

In some embodiments, the surface treatment includes a plasma treatment to the CNT membrane layer. The gas for plasma includes one or more of Ar, He, H₂, Ne, N₂ and NH₃, without oxygen. In some embodiments, O₂ is used alternatively or additionally. In some embodiments, the CNT membrane layer and/or the gas are heated at a temperature in a range from about 200° C. to 600° C. during the plasma treatment. In other embodiments, the temperature is in a range from about 300° C. to 500° C. The plasma is generated as capacitively coupled plasma, inductively coupled plasma, electron cyclotron plasma, hybrid cold plasma, glow discharge plasma or high pressure arc plasma. The input power of the plasma is in a range from about 1 W to about 2 KW in some embodiments.

In some embodiments, the hydroxyl or carbonyl functional groups 232 are formed on the surface of the CNT 230 by H₂O plasma or thermal H₂O₂.

In some embodiments, after the surface treatment, one or more post treatments may be performed. In some embodiments, the post treatment includes annealing, such as furnace annealing, rapid thermal annealing, laser annealing, UV annealing, or electron beam annealing.

In step 604 of the method 600, a seed layer 250 comprising a plurality of nanostructures 252 is formed on the surface of CNT 230, as shown in FIG. 7B. The nanostructures 252 are formed at the sites where the functional groups 232 are located. The functional groups 232 serve as the nucleation centers to initiate the growth of nanostructures 252. The nanostructures 252 may be nano-grains, nano-islands, nano-cubes, nanosheets, or combinations thereof and may be formed by a sol-gel process, E-beam evaporation, CVD, ALD, PEALD, electrodeposition, electroless deposition, or other suitable deposition techniques.

In step 606 of the method 600, a diffusion barrier layer 260 is deposited over at least the nanostructures 252, as shown in FIG. 7C or FIG. 7C′. In some embodiments, the deposition of the diffusion barrier layer 260 is catalyzed by the nanostructures 252. In some embodiments and as shown in FIG. 7C, the diffusion barrier layer 260 is deposited to only cover the nanostructures 252, leaving portions of the CNT 230 between the nanostructures 252 uncovered by the diffusion barrier layer 260. In some embodiments and as shown in FIG. 7C′, the diffusion barrier layer 260 is deposited over both the nanostructures 252 and the CNT 230 such that portions of the CNT 230 between the nanostructures 252 are also covered by the diffusion barrier layer 260. In some embodiments, the diffusion barrier layer 260 is formed as a conformal layer and is deposited by a conformal deposition process such as CVD or PECVD.

In step 608 of the method 600, a capping layer 270 is deposited over at least the diffusion barrier layer 260, as shown in FIG. 7D or FIG. 7D′. In instances where the diffusion barrier layer 260 is formed only over the nanostructures 252 (FIG. 7C), the capping layer 270 is formed in contact with both the diffusion barrier layer 260 and the CNT 230, as shown in FIG. 7D. In instances where the diffusion barrier layer 260 is formed over both the nanostructures 252 and the CNT 230 (FIG. 7C′), the capping layer 270 is formed in contact only with the diffusion barrier layer 260, as shown in FIG. 7D′. In some embodiments, the capping layer 270 is formed as a conformal layer and is deposited by a conformal deposition process such as CVD, PECVD, ALD, PEALD, thermal ALD, or PVD.

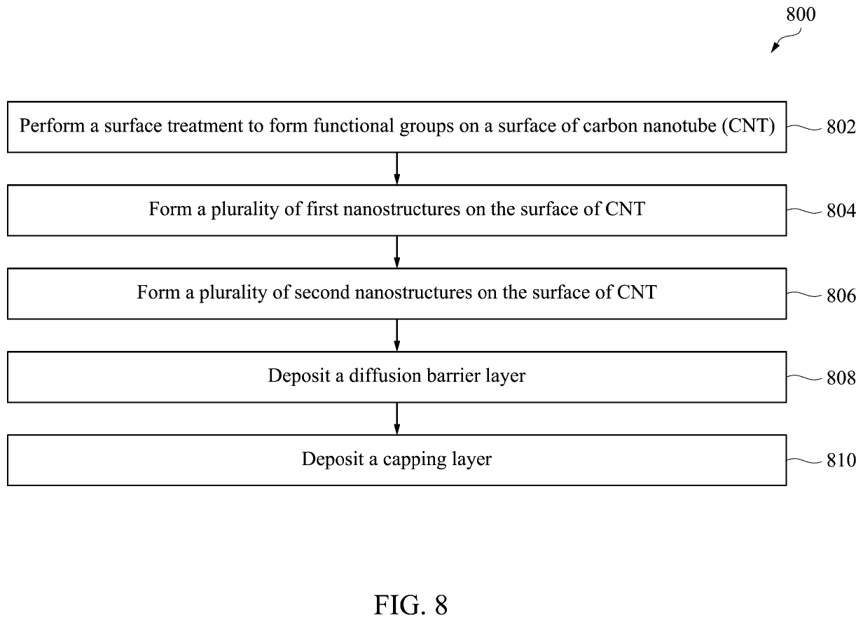

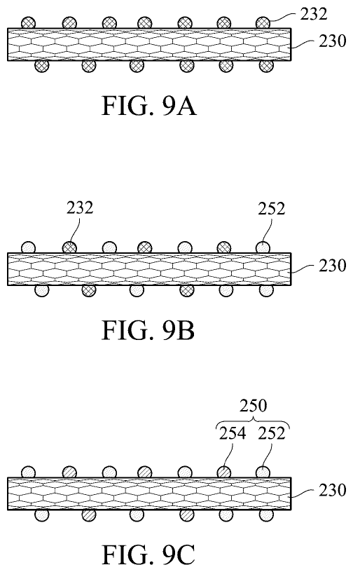

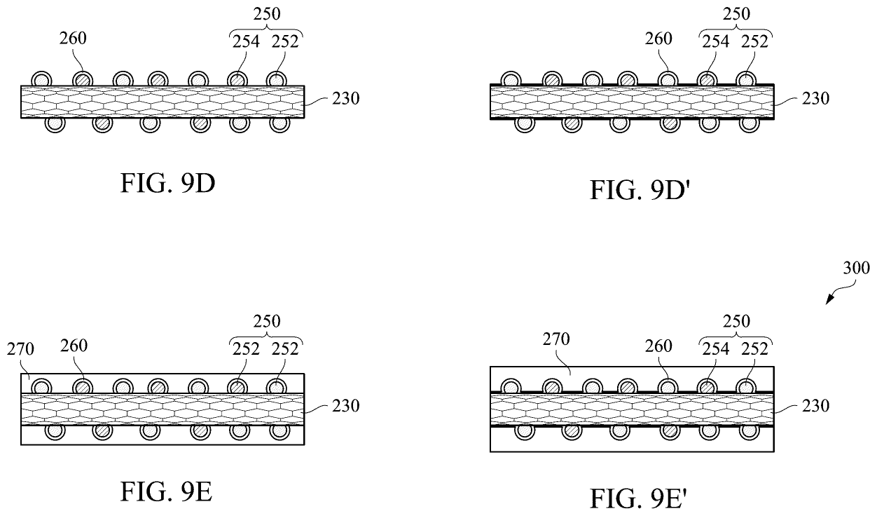

FIG. 8 is a flowchart illustrating a method 800 for forming a protection coating 240 on a CNT 230, in accordance with some embodiments. FIGS. 9A-9E′ are cross-sectional views of a coated CNT 300 at various stages of the method 800, in accordance with some embodiments. The method 800 is discussed in detail below, with reference to the coated CNT 300 of FIGS. 9A-9E′.

In step 802 of the method 800, a surface treatment is performed to form functional groups 232 on the CNT surface, as shown in FIG. 9A. The surface treatment can be carried out using various methods, such as using a solution, gas, or plasma, as described above in step 602 of the method 600.

In step 804 of the method 800, a plurality of first nanostructures 252 is formed on the surface of CNT 230, as shown in FIG. 9B. The first nanostructures 252 are formed at the sites where a first subset of the functional groups 232 are located. The first nanostructures 252 may be nano-grains, nano-islands, nano-cubes, nanosheets, or combinations thereof and may be formed by a sol-gel process, E-beam evaporation, CVD, ALD, PEALD, electrodeposition, electroless deposition, or other suitable deposition techniques.

In step 806 of the method 800, a plurality of second nanostructures 254 is formed on the surface of CNT 230, as shown in FIG. 9C. The second nanostructures 254 are formed at the sites where a second subset of the functional groups 232 are located. The second nanostructures 254 are composed of a different material than the material of the first nanostructures 252. The second nanostructures 254 may be nano-grains, nano-islands, nano-cubes, nanosheets, or combinations thereof and may be formed by a sol-gel process, E-beam evaporation, CVD, ALD, PEALD, electrodeposition, electroless deposition, or other suitable deposition techniques. The second nanostructures 254, along with the first nanostructures 252, form the seed layer 250.

In embodiments of the present disclosure, the use of two types of nanostructures (i.e., nanostructures 252, 254) made of different materials enables simultaneous optimization of hydrogen reduction capability and EUV light transmission properties of these nanostructures.

In step 808 of the method 800, a diffusion barrier layer 260 is deposited over at least first and second nanostructures 252, 254, as shown in FIG. 9D or FIG. 9D′. In some embodiments, the deposition of the diffusion barrier layer 260 is catalyzed by the first and second nanostructures 252, 254. In some embodiments and as shown in FIG. 9D, the diffusion barrier layer 260 is deposited to only cover the first and second nanostructures 252, 254, leaving portions of the CNT 230 between the first and second nanostructures 252, 254 uncovered by the diffusion barrier layer 260. In some embodiments and as shown in FIG. 9D′, the diffusion barrier layer 260 is deposited over both the first and nanostructures 252, 254 and the CNT 230 such that portions of the CNT 230 between the first and second nanostructures 252, 254 are also covered by the diffusion barrier layer 260. In some embodiments, the diffusion barrier layer 260 is formed as a conformal layer and is deposited by a conformal deposition process such as CVD or PECVD.

In step 810 of the method 800, a capping layer 270 is deposited over at least the diffusion barrier layer 260, as shown in FIG. 9E or FIG. 9E′. In instances where the diffusion barrier layer 260 is formed only over the first and second nanostructures 252, 254 (FIG. 9D), the capping layer 270 is formed in contact with both the diffusion barrier layer 260 and the CNT 230, as shown in FIG. 9E. In instances where the diffusion barrier layer 260 is formed over both the first and second nanostructures 252, 254 and the CNT 230 (FIG. 9D′), the capping layer 270 is formed in contact only with the diffusion barrier layer 260, as shown in FIG. 9E′. In some embodiments, the capping layer 270 is formed as a conformal layer and is deposited by a conformal deposition process such as CVD, PECVD, ALD, PEALD, thermal ALD, or PVD.

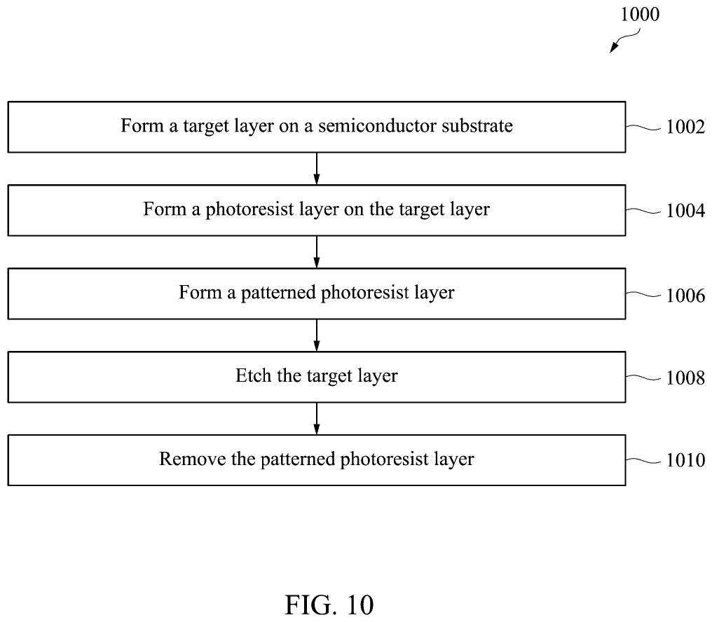

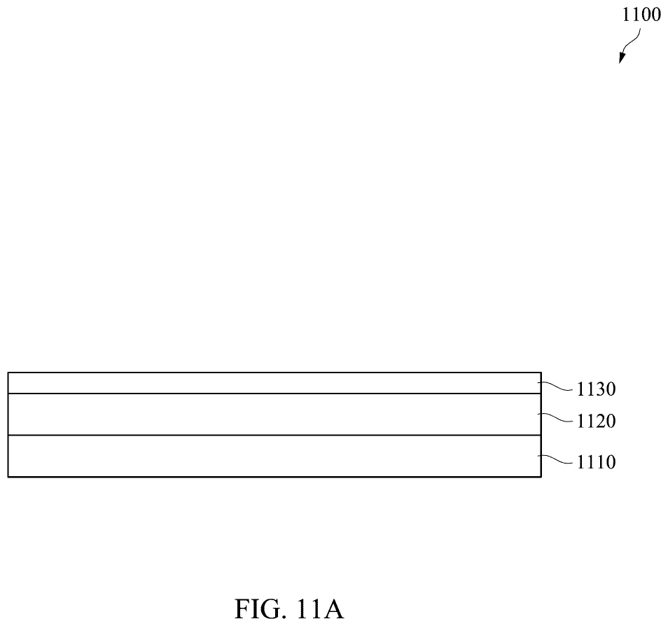

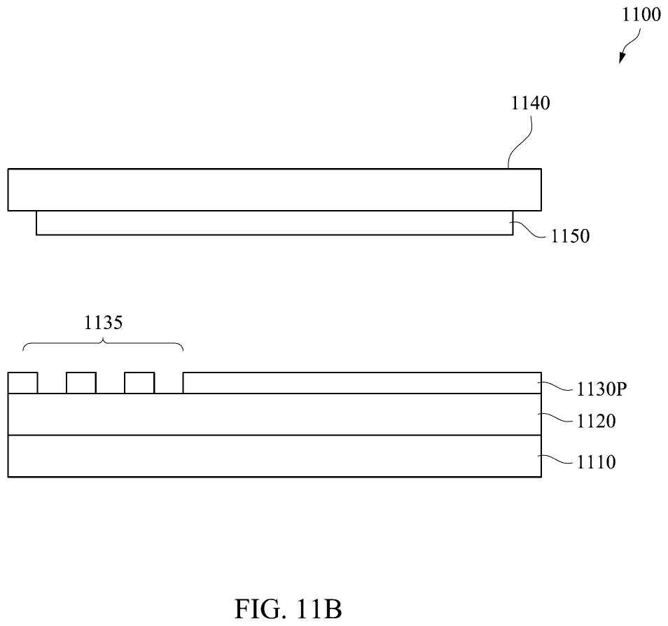

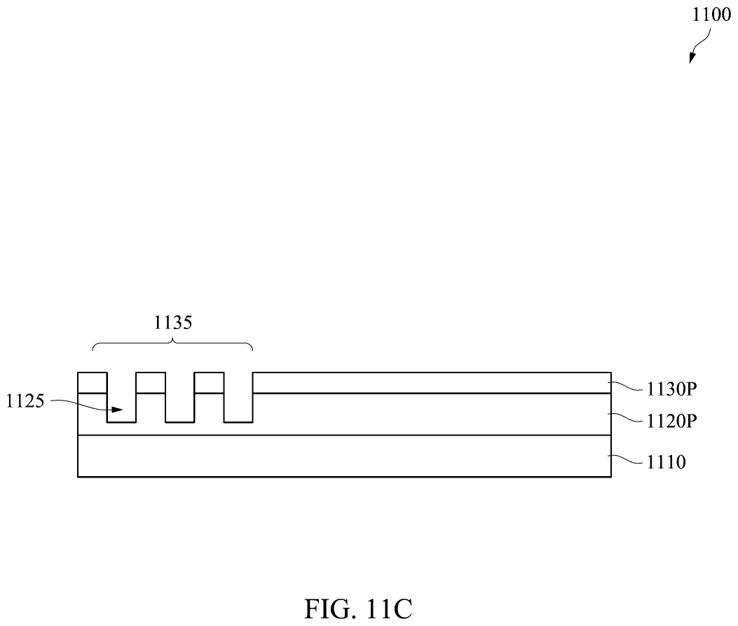

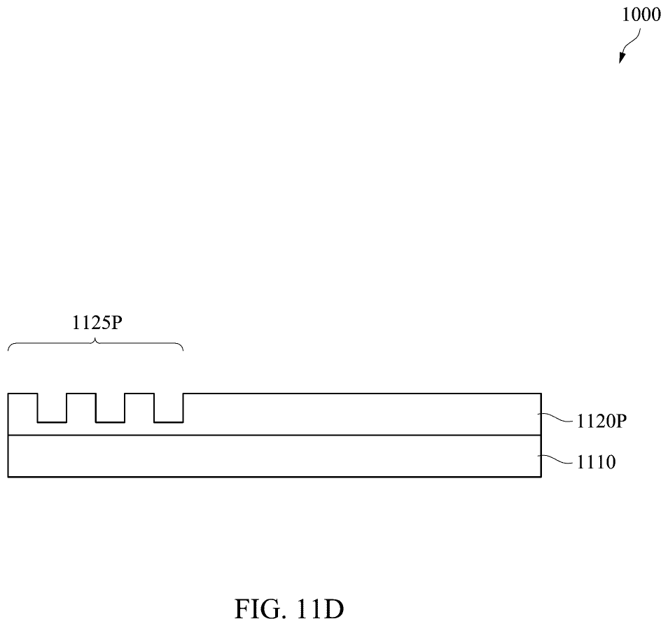

FIG. 10 is a flowchart illustrating a method 1000 for fabricating a semiconductor device, in accordance with some embodiments. FIGS. 11A-11D are cross-sectional views of the semiconductor device 1100 at various stages of the method 1000, in accordance with some embodiments. The method 1000 is discussed in detail below, with reference to the semiconductor devices of FIGS. 11A-11D. At least some steps of the method 1000 may be performed via control of an EUV lithography system, such as the lithography system of FIG. 1.

A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material.

In step 1002 of the method 1000, a target layer 1120 to be patterned is formed over a semiconductor substrate 1110, as shown in FIG. 11A. In certain embodiments, the target layer 1120 is the semiconductor substrate 1110. In some embodiments, the target layer 1120 includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer 1120 is formed over an underlying structure, such as isolation structures, transistors or wirings.

In step 1004 of the method 1000, a photoresist layer 1130 is formed over the target layer 1120, as shown in FIG. 11A. The photoresist layer 1130 is sensitive to the radiation from the exposing source during a subsequent photolithography exposing process. In some embodiments, the photoresist layer 1130 is sensitive to EUV light used in the photolithography exposing process. The photoresist layer 1130 may be formed over the target layer by spin-on coating or other suitable technique. The coated photoresist layer 1130 may be further baked to drive out solvent in the photoresist layer 1130.

In step 1006 of the method 1000, the photoresist layer 1130 is patterned using an EUV mask 11140 with a pellicle 1150 as set forth above, as shown in FIG. 11B. The pellicle 1150 includes a pellicle membrane as described herein. The pellicle membrane comprises at least one CNT membrane layer that contains a network of a plurality of CNTs with a least one CNT in the plurality of CNTs coated with a multilayer protection coating of the present disclosure. The patterning of the photoresist layer 1130 includes performing a photolithography exposing process by an EUV exposing system using the EUV photomask 1140. During the exposing process, light emitted by a EUV light source is directed onto the EUV photomask 1140. The light that passes through the pellicle 1150 and is reflected by the EUV photomask 1140 is then collected and directed to the photoresist layer 1130 by a projection optics module. The integrated circuit (IC) design pattern defined on the EUV photomask 1140 is imaged to the photoresist layer 1130 to form a latent pattern thereon. Falling particles during the exposing process may be caught by the pellicle membrane 226 so as to keep the EUV photomask 1140 clear of the falling particles while the light is being directed onto the EUV photomask 1140.

The patterning of the photoresist layer 1130 further includes developing the exposed photoresist layer to form a patterned photoresist layer 1130P having a plurality of openings 1135. In one embodiment where the photoresist layer 1130 is a positive tone photoresist layer, the exposed portions of the photoresist layer 1130 are removed during the developing process. The patterning of the photoresist layer 1130 may further include other process steps, such as various baking steps at different stages. For example, a post-exposure-baking (PEB) process may be implemented after the photolithography exposing process and before the developing process.

In step 1008 of the method 1000, the target layer 1120 is patterned utilizing the patterned photoresist layer 1130P as an etching mask, as shown in FIG. 11C. In some embodiments, the patterning the target layer 1120 includes applying an etching process to the target layer 1120 using the patterned photoresist layer 1130P as an etch mask. The portions of the target layer 1120 exposed within the openings 1135 of the patterned photoresist layer 1130P are etched while the remaining portions are protected from etching. Trenches 1125 are now present in the patterned target layer 1120P.

In step 1010 of the method 1000, the patterned photoresist layer 1130P may be removed by wet stripping or plasma ashing, as shown in FIG. 11D. Further processing steps can then be performed.

One aspect of this description relates to a pellicle. The pellicle includes a pellicle membrane comprising a plurality of carbon nanotubes (CNTs). At least one carbon nanotube (CNT) of the plurality of CNTs is coated by a protection coating. The protection coating includes a plurality of first nanostructures on a surface of the at least one CNT of the plurality of CNTs, a carbon-based diffusion barrier layer over at least the plurality of first nanostructures, and a capping layer over at least the carbon-based diffusion barrier layer. The plurality of first nanostructures includes a transition metal or an oxide, nitride, silicide or carbide thereof. The pellicle membrane further comprises a pellicle border attached to the pellicle membrane along a peripheral region of the pellicle membrane; and a pellicle frame attached to the pellicle border.

Another aspect of this description relates to a pellicle-photomask structure. The pellicle-photomask structure includes an extreme ultraviolet (EUV) photomask comprising a pattern region, and a pellicle attached to a peripheral region of the EUV photomask that includes a pellicle membrane extending across the pattern region of the EUV photomask. The pellicle membrane includes a plurality of carbon nanotubes (CNTs) covered by a protection coating. The protection coating includes a plurality of first nanostructures on a surface of the at least one CNT of the plurality of CNTs, a carbon-based diffusion barrier layer over the plurality of first nanostructures, and a capping layer over the carbon-based diffusion barrier layer.

Still another aspect of this description relates to a method for forming a pellicle to protect an extreme ultraviolet (EUV) photomask. The method includes forming a plurality of functional groups on surfaces of a plurality of carbon nanotubes (CNTs), growing a plurality of nanostructures on the surfaces of the plurality of CNTs using the plurality of functional groups as nucleation sites, forming a carbon-based diffusion barrier layer to encapsulate the plurality of nanostructures, and forming a conformal capping layer covering the carbon-based diffusion barrier layer and the plurality of CNTs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor device, comprising:
directing radiation to a photomask through a pellicle on the photomask, the pellicle comprising a pellicle membrane comprising a plurality of carbon nanotubes (CNTs), wherein at least one carbon nanotube (CNT) of the plurality of CNTs is coated by a protection coating, the protection coating comprising:
a plurality of nanostructures on a surface of the at least one CNT of the plurality of CNTs, the plurality of nanostructures comprising a transition metal or an oxide, nitride, silicide or carbide thereof;
a carbon-based diffusion barrier layer over at least the plurality of nanostructures; and
a capping layer over at least the carbon-based diffusion barrier layer; and
directed a portion of the radiation reflected from the photomask onto a photoresist layer on a substrate.

2. The method of claim 1, wherein the plurality of nanostructures comprises Co, Ir, Fe, Nb, Ni, Pt, Rh, Ru, Ti, RuO₂, RuSi₂, RuSi, Ru₂Si₃, Nb₂O₅, Mo, MoO₂, or TiO₂.

3. The method of claim 2, wherein the plurality of nanostructures comprises Ru or RuO₂.

4. The method of claim 1, wherein the nanostructures are uniformly distributed on the surface of the at least one CNT of the plurality of CNTs.

5. The method of claim 2, wherein the plurality of nanostructures comprises nano-grains, nano-islands, nano-cubes nano-sheets or combinations thereof.

6. The method of claim 1, wherein the carbon-based diffusion barrier layer comprises graphene, amorphous carbon, graphite, or diamond-like carbon.

7. The method of claim 6, wherein the carbon-based diffusion barrier layer comprises graphene.

8. The method of claim 1, wherein the capping layer is a conformal layer in contact with the carbon-based diffusion barrier layer and portions of the at least one CNT of the plurality of CNTs not covered by the carbon-based diffusion barrier layer.

9. The method of claim 8, wherein the capping layer comprises silicon dioxide (SiO₂) aluminum oxide (Al₂O₃), niobium oxide (Nb₂O₅), platinum dioxide (PtO₂), ruthenium oxide (RuO₂), titanium oxide (TiO₂), yttrium oxide (Y₂O₃), silicon nitride (SiN), aluminum nitride (AlN), titanium nitride (TiN), yttrium nitride (YN), boron nitride (BN), silicon oxynitride (SiON), aluminum oxynitride (AlON), titanium oxynitride (TiON), silicon carbide (SiC), silicon oxycarbide (SiOC) or yttrium oxysilicide (YOSi).

10. A method for fabricating a semiconductor device, comprising:
directing an extreme ultraviolet (EUV) radiation to a photomask of a pellicle-photomask structure, the pellicle-photomask structure comprising:
an EUV photomask comprising a pattern region; and
a pellicle attached to a peripheral region of the EUV photomask, the pellicle comprising a pellicle membrane extending across the pattern region of the EUV photomask, the pellicle membrane comprising a plurality of carbon nanotubes (CNTs), wherein the plurality of CNTs is covered by a protection coating comprising:
a plurality of first nanostructures on a surface of the at least one CNT of the plurality of CNTs;
a carbon-based diffusion barrier layer over the plurality of first nanostructures; and
a capping layer over the carbon-based diffusion barrier layer;
directing a portion of the EUV radiation reflected from the photomask onto a photoresist layer on a substrate;
developing the photoresist layer; and
transfer a pattern in the photoresist layer into the substrate.

11. The method of claim 10, wherein the protection coating further comprises a plurality of second nanostructures on the surface of the at least one CNT of the plurality of CNTs, wherein the plurality of first nanostructures and the plurality of second nanostructures are composed of different materials.

12. The method of claim 11, wherein the first nanostructures are separated from each other by one or more of the second nanostructures.

13. The method of claim 11, wherein the plurality of first nanostructures comprises Ru, RuO₂, RuSi₂, RuSi or Ru₂Si₃.

14. The method of claim 11, wherein the plurality of second nanostructures comprises Nb, Nb₂O₅, Mo, MoO₂, Ti, TiO₂, Ir, Pt, Rh, Ni, Fe or Co.

15. The method of claim 10, wherein the carbon-based diffusion barrier layer comprises graphene.

16. The method of claim 10, wherein the carbon-based diffusion barrier layer is a discontinued layer present only on exposed surfaces of the plurality of first nanostructures.

17. The method of claim 10, wherein the carbon-based diffusion barrier layer is a continuous conformal layer present on exposed surfaces of the plurality of first nanostructures and the plurality of CNTs.

18. The method of claim 10, wherein the capping layer comprises silicon dioxide (SiO₂) aluminum oxide (Al₂O₃), niobium oxide (Nb₂O₅), platinum dioxide (PtO₂), ruthenium oxide (RuO₂), titanium oxide (TiO₂), yttrium oxide (Y₂O₃), silicon nitride (SiN), aluminum nitride (AlN), titanium nitride (TiN), yttrium nitride (YN), boron nitride (BN), silicon oxynitride (SiON), aluminum oxynitride (AlON), titanium oxynitride (TiON), silicon carbide (SiC), silicon oxycarbide (SiOC) or yttrium oxysilicide (YOSi).

19. A method for fabricating a semiconductor device, comprising:
directing an extreme ultraviolet (EUV) radiation to a photomask of a pellicle-photomask structure, the pellicle-photomask structure comprising:
an EUV photomask comprising a pattern region; and
a pellicle attached to a peripheral region of the EUV photomask, the pellicle comprising a pellicle membrane extending across the pattern region of the EUV photomask, the pellicle membrane comprising a plurality of carbon nanotubes (CNTs), wherein the plurality of CNTs is covered by a protection coating comprising:
a plurality of first nanostructures on a surface of the at least one CNT of the plurality of CNTs, the plurality of first nanostructures comprising a first material;
a plurality of second nanostructures on the surface of the at least one CNT of the plurality of CNTs, the plurality of second nanostructures comprising a second material different from the first material
a carbon-based diffusion barrier layer on the surface of the at least one CNT of the plurality of CNTs to encapsulate the plurality of first nanostructures and the plurality of second nanostructures; and
a capping layer over the carbon-based diffusion barrier layer;
directing a portion of the EUV radiation reflected from the photomask onto a photoresist layer on a substrate;
developing the photoresist layer to form a patterned photoresist layer; and
etching the substrate using the patterned photoresist layer as an etch mask.

20. The method of claim 18, wherein the plurality of first nanostructures comprises Ru, RuO₂, RuSi₂, RuSi or Ru₂Si₃, and the plurality of second nanostructures comprises Nb, Nb₂O₅, Mo, MoO₂, Ti, TiO₂, It, Pt, Rh, Ni, Fe or Co.
